(19) United States
(12) Patent Application Publication
(10) Pub. No.: US 2025/0060408 A1
(43) Pub. Date: Feb. 20, 2025

(54) PREDICTION DEVICE, TEST SYSTEM, PREDICTION METHOD, AND PREDICTION PROGRAM

(71) Applicant: Tokyo Electron Limited, Tokyo (JP)

(72) Inventor: Hiroaki HAYASHI, Yamanashi (JP)

(21) Appl. No.: 18/720,848

(22) PCT Filed: Dec. 15, 2022
(86) PCT No.: PCT/JP2022/046228

§ 371 Date: Jun. 17, 2024

(30) Foreign Application Priority Data
Dec. 27, 2021 (JP) 2021-212972

(51) Int. Cl. G01R 31/28

(52) U.S. Cl. CPC G01R 31/2882; G01R 31/287

(57) ABSTRACT

Information for realizing an efficient transfer schedule by the transfer section is provided. A prediction device includes a calculation unit configured to calculate a test time length when a test of a wafer has been performed by a tester; a test time prediction unit configured to predict a current test time length based on past test time lengths calculated by the calculation unit; an end time prediction unit configured to predict, when a start time of a test of a test target wafer by the tester is acquired, an end time of the test of the test target wafer based on the predicted test time length; and a storage unit configured to store at least the predicted test time length and the predicted end time in a readable manner.

### TECHNICAL FIELD

The present disclosure relates to a prediction device, a test system, a prediction method, and a prediction program.

### BACKGROUND

A test system, in which multiple testers (test sections) configured to test electrical characteristics of wafers are arranged and multiple wafers are simultaneously tested by transferring the wafers to the respective testers, is known. In the test system, each of the testers executes the same test program, and each time the test is completed, the transfer section collects a wafer from a corresponding tester and transfers a next wafer to the tester.

Here, the time length required to test a wafer depends on the electrical characteristics of the wafer and the like, and thus, even when the same test program is executed, the time length required to test a wafer differs from wafer to wafer. Therefore, in the test system, the tester notifies the transfer section of the end of the test, and then the transfer section starts the operations of collecting, transferring, and the like. However, when a transfer schedule is set such that the operation of the transfer section is started by the notification of the end of the test by the tester as a trigger, the operation rate of the tester is limited.

### RELATED ART DOCUMENT

### Patent Document

[Patent Document 1] Japanese Laid-open Patent Application Publication No. 2019-621138

### SUMMARY OF THE INVENTION

### Problem to be Solved by the Invention

The present disclosure provides information for realizing an efficient transfer schedule by a transfer section.

### Means for Solving the Problem

A prediction device according to an aspect of the present disclosure has, for example, the following configuration. That is, the prediction device includes a calculation unit configured to calculate a test time length when a test of a wafer has been performed by a tester; a test time prediction unit configured to predict a current test time length based on past test time lengths calculated by the calculation unit; an end time prediction unit configured to predict, when a start time of a test of a test target wafer by the tester is acquired, an end time of the test of the test target wafer based on the predicted test time length; and a storage unit configured to store at least the predicted test time length and the predicted end time in a readable manner.

### Effect of the Invention

According to the present disclosure, information for realizing an efficient transfer schedule by a transfer section can be provided.

### BRIEF DESCRIPTION OF THE DRAWINGS

FIG. 1 is a first diagram illustrating a configuration example of a test device.

FIG. 2 is a second diagram illustrating a configuration example of the test device.

FIG. 3 is a first diagram illustrating an example of a system configuration of a test system.

FIG. 4 is a diagram illustrating an example of a hardware configuration of a prediction device.

FIG. 5 is a diagram illustrating an example of variations in test time lengths from wafer to wafer.

FIG. 6 is a diagram illustrating an example of a functional configuration of a measured data collection unit.

FIG. 7 is a diagram illustrating an example of measured data stored in a measured data storage unit.

FIG. 8 is a diagram illustrating an example of a functional configuration of a test time prediction unit.

FIG. 9 is a diagram illustrating an example of a functional configuration of a table generation unit and an example of a generated table.

FIG. 10 is an example of a first flowchart illustrating a flow of a prediction process.

FIG. 11 is an example of a second flowchart illustrating the flow of the prediction process.

FIG. 12 is a second diagram illustrating the example of the system configuration of the test system.

### DESCRIPTION OF THE EMBODIMENTS

In the following, each embodiment will be described with reference to the accompanying drawings. Here, in the present specification and drawings, components having substantially the same functional configuration are denoted by the same reference symbols, and duplicated description thereof will be omitted.

### First Embodiment

### <Outline of Test Device>

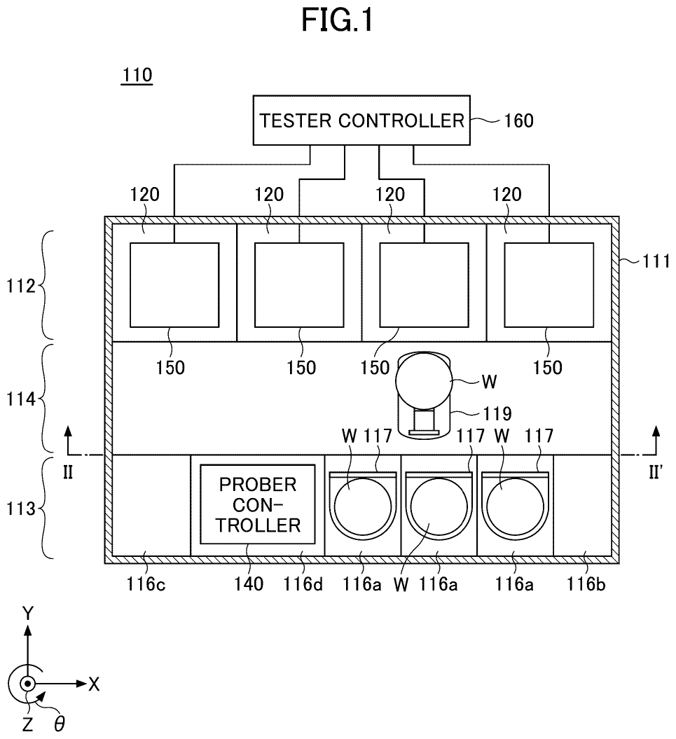

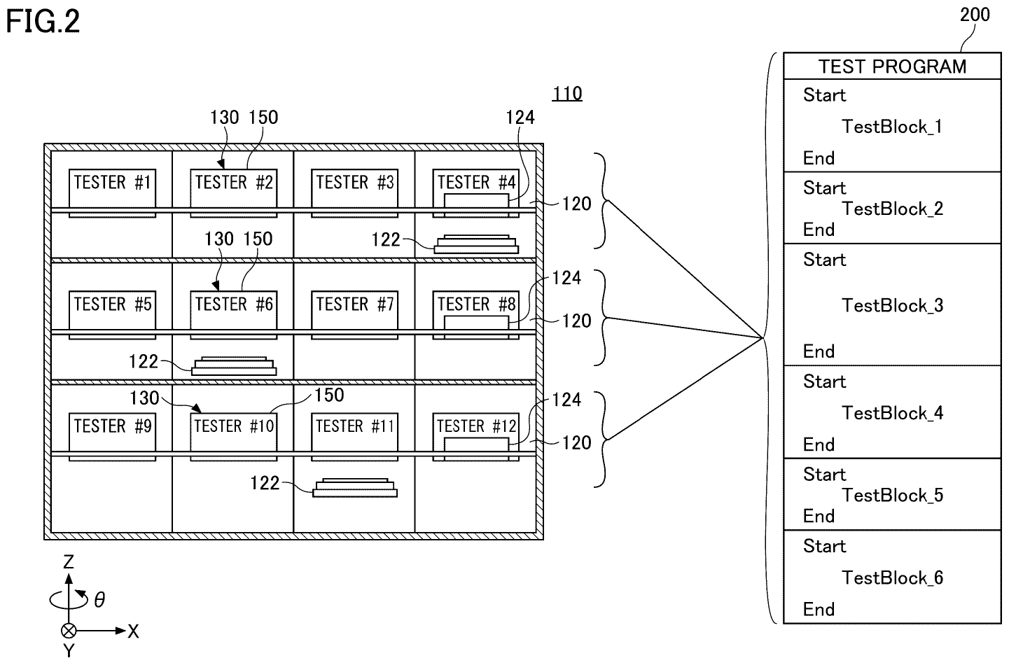

First, an overview of a test device constituting a test system according to a first embodiment will be described with reference to FIG. 1 and FIG. 2. FIG. 1 and FIG. 2 are first and second diagrams illustrating an example of a configuration of the test device, FIG. 1 illustrates a horizontal section of the test device, and FIG. 2 illustrates a vertical section taken along the line II-II′ of FIG. 1. In the first embodiment, a test device 110 tests electrical characteristics of multiple devices under test (DUT, hereinafter simply referred to as devices) formed on a wafer, which is a test target.

The test device 110 includes multiple testers (test sections) and a prober. The prober includes:
a mechanism for transferring wafers to multiple testers;
a wafer stage (chuck top) configured to hold a wafer by suction in correspondence with each tester; and
an interface such as a probe card for electrical connection between the devices formed on the wafer and the tester.

In FIG. 1, the test device 110 includes a housing 111, and the housing 111 includes:
a test region 112 for testing electrical characteristics of the devices formed on the wafer W;
a carry-in/out region 113 for carrying the wafer W or the probe card into and out of the test region 112 and having a control system; and
a transfer region 114 provided between the test region 112 and the carry-in/out region 113.

In the test region 112, as illustrated in FIG. 2, four test chambers 120 are arranged along the X direction, and such test chamber rows are arranged in three stages in the Z direction (the vertical direction). A tester 150 configured to test electrical characteristics of the devices formed on the wafer W is disposed in each of the test chambers 120. The testers 150 are controlled by a tester controller 160.

Additionally, in each stage of the test region 112, one aligner 122 that functions as a wafer transfer stage movable in the X direction is provided below the testers 150 for the test chambers 120 arranged in the X direction. Further, each stage of the test region 112 is provided with one upper camera 124, for alignment, movable along the X direction in a region that is closer to the transfer region 114 than the tester 150 is.

The carry-in/out region 113 is partitioned into multiple ports. The multiple ports include multiple wafer carry-in/out ports 116a each accommodating a FOUP 117, which is a container accommodating multiple wafers W, and a pre-alignment section 116b configured to perform alignment of a wafer to be transferred. Additionally, the multiple ports include a probe card loader 116c into and from which the probe card is carried, and a control port 116d in which a prober controller 140 configured to control an operation of the prober of the test device 110 is accommodated.

A transfer mechanism 119 including multiple transfer arms is disposed in the transfer region 114. A main body of the transfer mechanism 119 is movable in the Z direction and the θ direction, and the transfer arm is movable in the front-rear direction. This allows the transfer mechanism 119 to move the wafer W in the X direction, the Y direction, the Z direction, and the θ direction. Additionally, the transfer mechanism 119 can access the test chambers 120 of all the stages. Specifically, the transfer mechanism 119 receives the wafer W from the wafer carry-in/out port 116a of the carry-in/out region 113 and transfers the wafer W to a chuck top (a wafer stage) in a test unit 130. Additionally, the transfer mechanism 119 receives the wafer W whose electrical characteristics of devices have been tested from the chuck top of the corresponding test unit 130, and transfers the wafer W to the wafer carry-in/out port 116a. The transfer of the wafer W to and from the chuck top at this time is performed using the aligner 122, and the aligner 122 and the transfer mechanism 119 form a transfer section of the wafer W.

Additionally, the transfer mechanism 119 transfers a probe card that requires maintenance from each test chamber 120 to the probe card loader 116c, and transfers a new probe card or a probe card after maintenance to each test chamber 120.

In each of the test chambers 120, the test unit 130 including the tester 150 and other elements required for the test is arranged.

Here, a test program 200 illustrated in FIG. 2 is a test program executed by each of the testers 150 (tester name=“tester #1” to “tester #12” in the example of FIG. 2) that tests the electrical characteristics of the devices formed on the wafer W. Each of the testers 150 executes the test program 200. That is, in the case of the test device 110, the electrical characteristics of the devices can be tested for 12 (twelve) sheets of wafers W at the same time.

As illustrated in FIG. 2, in the present embodiment, six blocks constitute the test program 200, and tests of different test items are sequentially performed on one wafer W. In the example of FIG. 2, the six block names are “TestBlock_1” to “TestBlock_6”.

### <System Configuration of Test System>

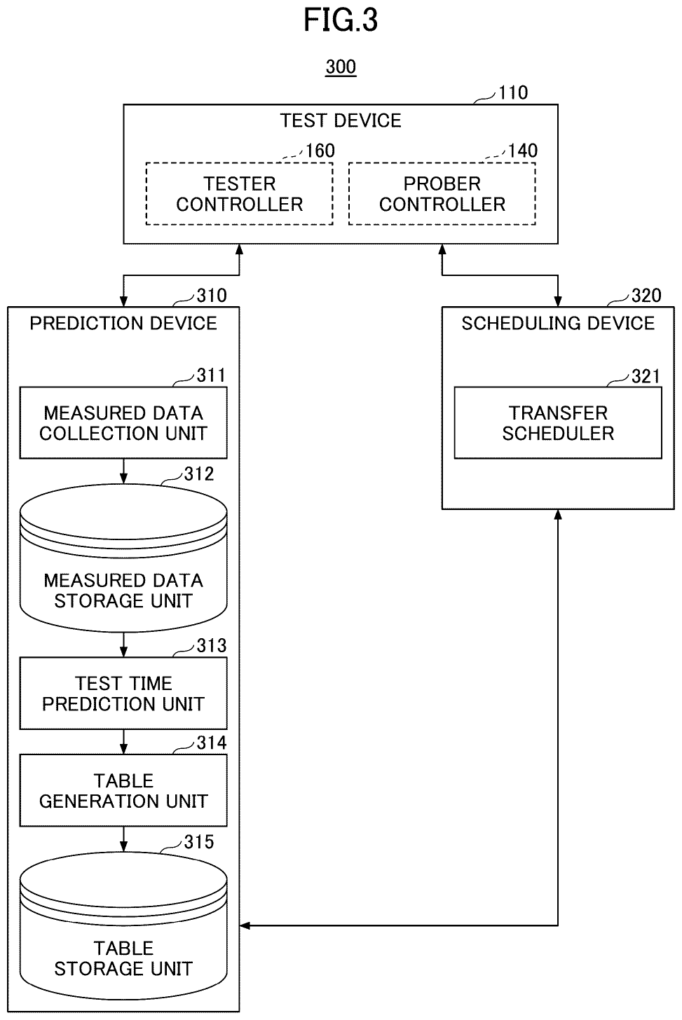

Next, a system configuration of the test system according to the first embodiment will be described. FIG. 3 is a diagram illustrating an example of the system configuration of the test system. As illustrated in FIG. 3, a test system 300 includes the test device 110, a prediction device 310, and a scheduling device 320.

Here, the test device 110, the prediction device 310, and the scheduling device 320 may be configured as separate devices as illustrated in FIG. 3, or may be integrally configured. Alternatively, either the prediction device 310 or the scheduling device 320 may be integrally configured with the test device 110.

When the prediction device 310 and the test device 110 are integrally configured, for example, a function of the prediction device 310 may be implemented in the tester controller 160. Additionally, when the scheduling device 320 and the test device 110 are integrally configured, for example, a function of the scheduling device 320 may be implemented in the prober controller 140.

In the test system 300 illustrated in FIG. 3, the test device 110 has been described with reference to FIG. 1 and FIG. 2, and therefore, the prediction device 310 and the scheduling device 320 will be described here.

A prediction program is installed in the prediction device 310, and by the prediction program being executed, the prediction device 310 functions as a measured data collection unit 311, a test time prediction unit 313, and a table generation unit 314.

The measured data collection unit 311 acquires the start time and the end time when each tester 150 of the test device 110 tests the electrical characteristics of the devices formed on the wafer W. Specifically, the measured data collection unit 311 acquires:
a test start time when each tester 150 starts a test
a block execution start time when each tester 150 starts execution of each block
a block execution end time when each tester 150 ends execution of each block
a test end time when each tester 150 ends the test. Here, the test start time is equal to the block execution start time of the block: the block name=“TestBlock1”, and the test end time is equal to the block execution end time of the block: the block name=“TestBlock6”.

Additionally, the measured data collection unit 311 calculates the test time length of each tester 150 for each wafer W based on the acquired test start time and test end time of the tester 150. Additionally, the measured data collection unit 311 calculates the block execution time length of each block for each wafer W based on the acquired execution start time and block execution end time of each block.

Further, the measured data collection unit 311 stores the acquired test start time and test end time of each tester 150, the calculated test time length of each tester 150, and the calculated block execution time length of each block in the measured data storage unit 312 as measured data for each wafer W.

The test time prediction unit 313 reads the measured data stored in the measured data storage unit 312, and predicts a block execution time length of each block and a test time length when the electrical characteristics of the devices of the wafer W of the test target are tested by a corresponding tester. Additionally, the test time prediction unit 313 acquires the test start time and the block execution start time of the wafer W of the test target from the measured data collection unit 311. Then, the test time prediction unit 313 predicts the test end time by adding the predicted test time length (a test time prediction value) or the predicted block execution time length (a block execution time prediction value) to the acquired test start time and block execution start time.

When the devices formed on the wafer W are tested in each tester 150, the table generation unit 314 generates a table recording at least
the test time prediction value of each tester that is predicted by the test time prediction unit 313; and
the test end time (the predicted end time) of each tester 150 that is predicted by the test time prediction unit 313.
   Additionally, the table generation unit 314 stores the generated table in a table storage unit 315 in an accessible manner.

A transfer scheduling program is installed in the scheduling device 320, and by the transfer scheduling program being executed, the scheduling device 320 functions as a transfer scheduler 321.

The transfer scheduler 321 accesses the table storage unit 315 of the prediction device 310 and reads the predicted end time of each tester 150 that is recorded in the table. Additionally, the transfer scheduler 321 generates a transfer schedule of the transfer section based on the read predicted end time and notifies the prober controller 140 of the transfer schedule.

As described above, in the test system 300 according to the first embodiment, the test end time in each tester 150 is predicted based on the measured data, and the transfer schedule is generated based on the predicted end time.

This can improve the operation rate of each tester 150 in comparison with the case where the transfer section starts the operation after each tester 150 notifies that the test has ended. That is, the prediction device 310 according to the first embodiment can provide appropriate information (the table) for realizing an efficient transfer schedule by the transfer section.

### <Hardware Configuration of Prediction Device>

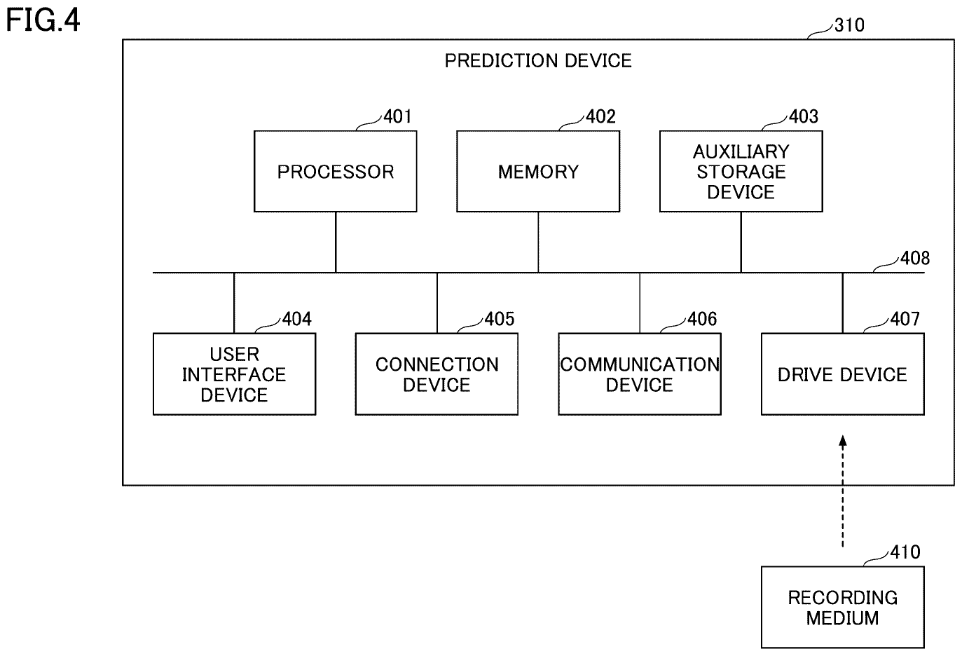

Next, a hardware configuration of the prediction device 310 will be described. FIG. 4 is a diagram illustrating an example of the hardware configuration of the prediction device.

As illustrated in FIG. 4, the prediction device 310 includes a processor 401, a memory 402, an auxiliary storage device 403, a user interface device 404, a connection device 405, a communication device 406, and a drive device 407. Here, hardware components of the prediction device 310 are connected to each other via a bus 408.

The processor 401 includes various arithmetic devices, such as a central processing unit (CPU), a graphics processing unit (GPU), and the like. The processor 401 reads various programs (for example, a prediction program and the like) onto the memory 402 and executes the programs.

The memory 402 includes a main storage device, such as a read only memory (ROM), a random access memory (RAM), or the like. The processor 401 and the memory 402 form what is called a computer, and by the processor 401 executing various programs read on the memory 402, the computer realizes the various functions.

The auxiliary storage device 403 stores various programs and various information used when the processor 401 executes the various programs. Here, the measured data storage unit 312 and the table storage unit 315 are implemented by the auxiliary storage device 403.

The user interface device 404 includes, for example, a keyboard or a touch panel used when a user of the prediction device 310 performs an input operation of various commands and the like, a display for displaying processing contents of the prediction device 310, and the like.

The connection device 405 is a connection device that connects to other devices (the test device 110, the scheduling device 320, and the like) in the test system 300. The communication device 406 is a communication device for communicating with an external device, which is not illustrated, via a network.

The drive device 407 is a device for setting a recording medium 410. The recording medium 410 herein includes a medium for optically, electrically, or magnetically recording information, such as a CD-ROM, a flexible disk, and a magneto-optical disk. Additionally, the recording medium 410 may include a semiconductor memory and the like that electrically record information, such as a ROM, a flash memory, or the like.

Here, the various programs installed in the auxiliary storage device 403 are installed by, for example, the distributed recording medium 410 being set in the drive device 407 and the drive device 407 reading the various programs recorded in the recording medium 410. Alternatively, the various programs installed in the auxiliary storage device 403 may be installed by being downloaded from a network via the communication device 406.

### <Variations in Test Time Lengths From Wafer to Wafer>

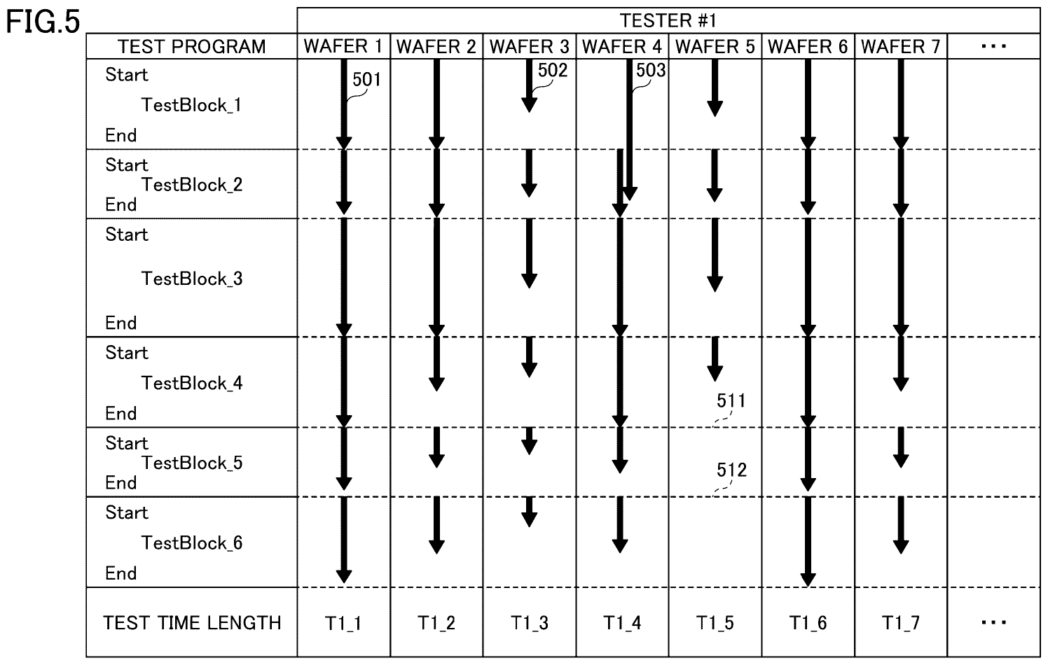

Next, the variations in the test time lengths from wafer W to wafer W in the tester 150 will be described. FIG. 5 is a diagram illustrating an example of the variations in the test time lengths from wafer to wafer. In FIG. 5, as an example, the block execution time length of each wafer W (the wafers W having wafer name=“wafer 1” to “wafer 7”) and the test time length of all blocks in the tester 150 having the tester name=“tester #1” and blocks having block names =“TestBlock_1” to “TestBlock_6” are illustrated.

The length of each arrow in FIG. 5 indicates the length of the block execution time of each block. For example, an arrow 501 indicates that, in the case of the wafer W having the wafer name=“wafer 1”, the execution of the block having the block name=“TestBlock_1” is completed in a standard block 1 execution time length.

Additionally, an arrow 502 indicates that, in the case of the wafer W having the wafer name=“wafer 3”, the execution of the block having the block name=“TestBlock_1” is completed in a time length shorter than the standard execution time length of the block 1. Additionally, an arrow 503 indicates that, in the case of the wafer W having the wafer name=“wafer 4”, the execution of the block having the block name=“TestBlock_1” is completed in a time length longer than the standard block 1 execution time length.

As described above, even in the test of the same block in the same tester 150, the block execution time length varies for each wafer W. This is because the electrical characteristics of the devices are different for each wafer W as described above. Even when the ratio of acceptable products is high (that is, the yield is high) and the wafer W of the test target is actually an acceptable product, the block execution time length varies if the electrical characteristics of the devices are different. Here, generally, the block execution time length has the following tendency, for example.
Immediately after a manufacturing process for manufacturing the wafer W is started for the very first time, the yield is not stable, and thus the block execution time length is long and varies greatly. Additionally, when the yield becomes stable as the time passes, the block execution time length becomes shorter and the variation becomes smaller.
In view of each tester, as the block proceeds, the yield decreases and the block execution time length becomes shorter.
The wafers W manufactured through the same manufacturing process (that is, the wafers W of the same lot) have substantially the same length of the block execution time in each block.

The prediction device 310 according to the present embodiment predicts the test time length of each tester and the block execution time length of each block of each tester based on the above-described tendency.

Here, in FIG. 5, fields (reference numerals 511 and 512) in which no arrow is described indicate that a corresponding wafer has been determined to be defective when a block previous to the corresponding block has been executed, and thus the corresponding block is not executed.

For example, the wafer W having the wafer name=“wafer 5” has been determined to be defective when the block having the block name=“TestBlock_4” has been executed. Thus, the test program is terminated without executing the subsequent blocks (block names=“TestBlock_5” and “TestBlock_6”).

Additionally, as illustrated in FIG. 5, the prediction device 310 according to the present embodiment calculates the test time length with respect to the wafer W for which the execution of the block having the block name=“TestBlock_6” is completed. The test time length is calculated by adding the block execution time lengths of all the blocks for each wafer W. In the example of FIG. 5, the test time lengths=“T1_1”, “T1_2”, “T1_3”, “T1_4”, “T1_6”, and “T1_7” are calculated with respect to the wafers W of the wafer names=“wafer 1” to “wafer 4”, “wafer 6”, and “wafer 7”.

### <Details of Functional Units of Prediction Device>

Next, functional units (the measured data collection unit 311, the test time prediction unit 313, and the table generation unit 314) of the prediction device 310 will be described in detail.

### (1) Details of Measured Data Collection Unit

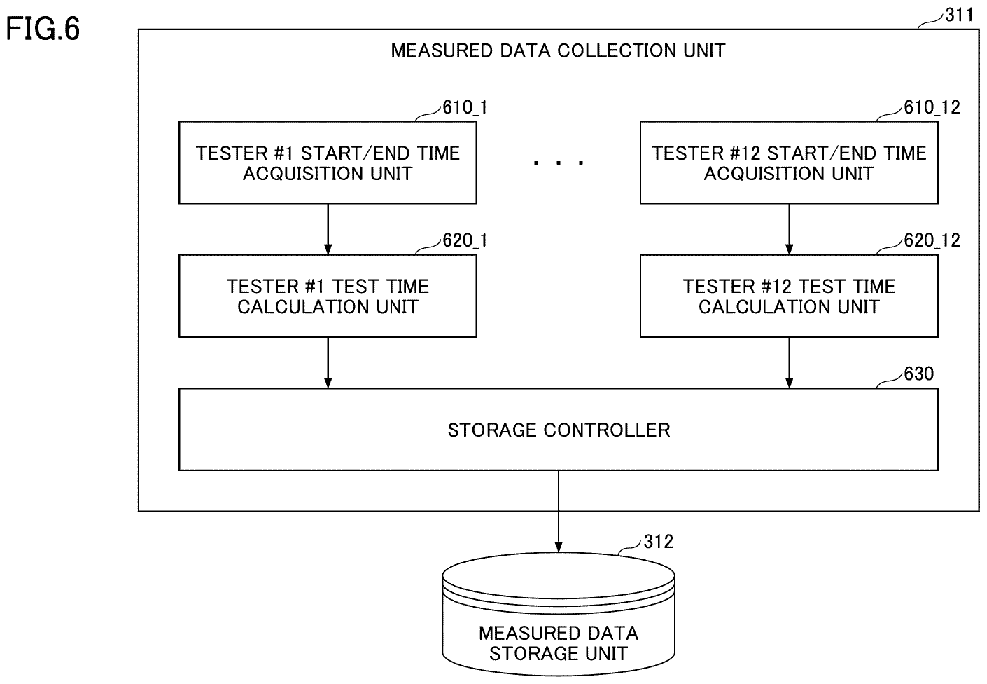

First, a functional configuration of the measured data collection unit 311 will be described. FIG. 6 is a diagram illustrating an example of the functional configuration of the measured data collection unit. As illustrated in FIG. 6, the measured data collection unit 311 includes:
a tester #1 start/end time acquisition unit 610_1 to a tester #12 start/end time acquisition unit 610_12;
a tester #1 test time calculation unit 620_1 to a tester #12 test time calculation unit 620_12; and.
a storage controller 630.

The tester #1 start/end time acquisition unit 610_1 to the tester #12 start/end time acquisition unit 610_12 acquire:
a test start time and a test end time of a corresponding tester 150; and
a block execution start time and a block execution end time of each block of the corresponding tester 150, for each wafer W.

The tester #1 test time calculation unit 620_1 to the tester #12 test time calculation unit 620_12 calculate the test time length by subtracting the test start time of the corresponding tester 150 from the test end time of the corresponding tester 150. Additionally, the tester #1 test time calculation unit 620_1 to the tester #12 test time calculation unit 620_12 calculate the block execution time length by subtracting the block execution start time of each block of the corresponding tester 150 from the block execution end time of the corresponding block of the corresponding tester 150.

The storage controller 630 stores the test start time and the test end time of each tester 150, the test time length of each tester 150, and the block execution time length of each block of each tester 150 in the measured data storage unit 312 for each wafer W.

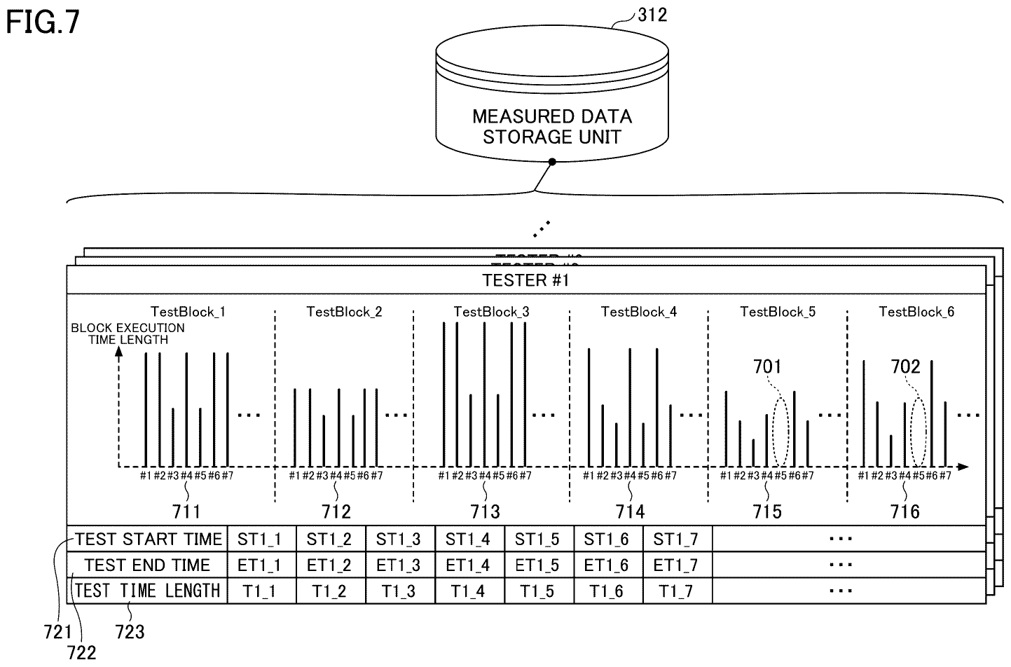

In FIG. 7, graphs 711 to 716 represent the block execution time lengths of the blocks (“Test Block 1” to “Test Block 6”) of the tester having the tester name=“tester #1” for each wafer W. In the graphs 711 to 716, the horizontal axis represents the number of the wafer, and the vertical axis represents the block execution time length. Here, reference numerals 701 and 702 in the graphs 715 and 716 are outliers. The outlier is information indicating a machine difference, disturbance, failure, or the like, and is used in comparison with other testers. For example, the outliers stored in the measured data storage unit 312 may be sequentially read and compared with the corresponding block execution time length of another tester to analyze the cause of occurrence.

Additionally, in FIG. 7, reference numerals 721 to 723 indicate a state in which the test start time, the test end time, and the test time length of the tester 150 having the tester name=“tester #1” are stored for each wafer W.

The test start time=“ST1_1” indicates the test start time when the first wafer W is tested in the tester 150 having the tester name=“tester #1”. Additionally, the test start time=“ST1_2” indicates the test start time when the second wafer W is tested by the tester having the tester name=“tester #1”.

The test end time=“ET1_1” indicates the test end time when the test of the first wafer W is completed in the tester 150 having the tester name=“tester #1”. Additionally, the test end time=“ET1_2” indicates the test end time when the test of the second wafer W is completed in the tester 150 having the tester name=“tester #1”.

The test time length=“T1_1” indicates the test time length (=“ET1_1”−“ST1_1”) of the first wafer W in the tester 150 having the tester name=“tester #1”. Additionally, the test time=“T1_2” indicates the test time length (=“ET1_2”−“ST1_2”) of the second wafer W in the tester 150 having the tester name=“tester #1”.

As described, every time the test of the wafer W of the test target is completed in each of the testers 150 having the tester names=“tester #1” to “tester #12”, the measured data storage unit 312 accumulates:
the block execution time length of each block;
the test start time;
the test end time; and
the test time length.

Here, in the measured data stored in the measured data storage unit 312 by the storage controller 630, measured data stored for a predetermined period of time may be automatically deleted. Alternatively, in measured data stored for a predetermined period of time, the block execution time length and the test time length may be compressed and stored as data indicating a past tendency by performing processing of calculating a variance value, processing of calculating an average value, or the like for each predetermined time range.

### (2) Details of Test Time Prediction Unit

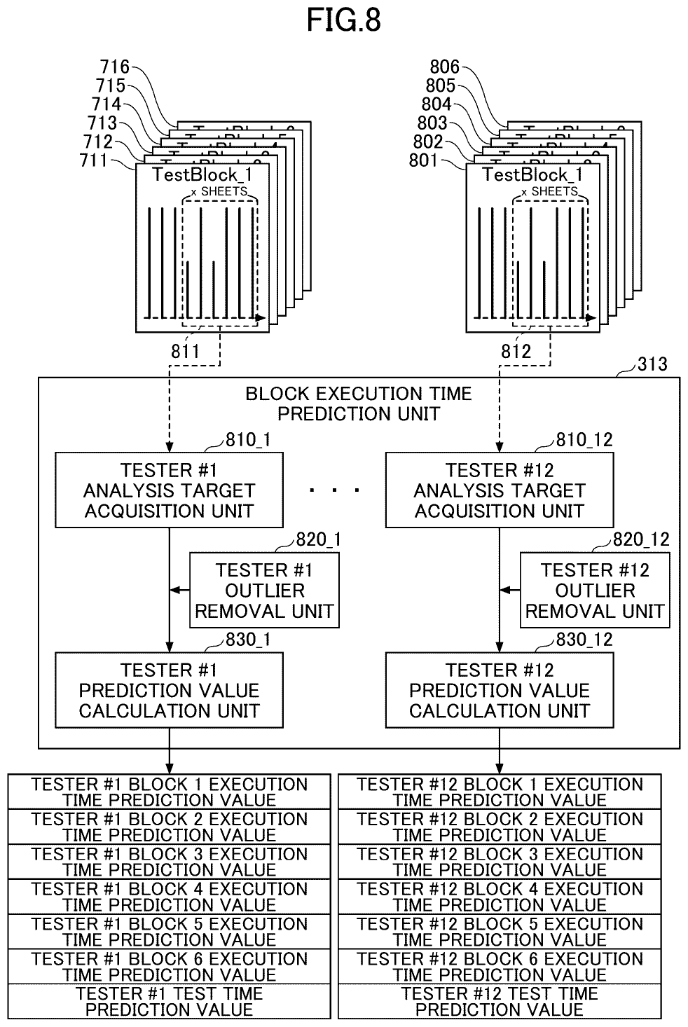

Next, a functional configuration of the test time prediction unit 313 will be described. FIG. 8 is a diagram illustrating an example of the functional configuration of the test time prediction unit. As illustrated in FIG. 8, the test time prediction unit 313 includes:
a tester #1 analysis target acquisition unit 810_1 to a tester #12 analysis target acquisition unit 810_12;
a tester #1 outlier removal unit 820_1 to a tester #12 outlier removal unit 820_12; and
a tester #1 prediction value calculation unit 830_1 to a tester #12 prediction value calculation unit 830_12.

The tester #1 analysis target acquisition unit 810_1 to the tester #12 analysis target acquisition unit 810_12 acquire, as analysis targets, block execution time lengths of respective blocks corresponding to a predetermined number of wafers W among the block execution time lengths of the blocks of the corresponding tester 150. The predetermined number of wafers W here indicates, for example, the latest x sheets of wafers W (see reference numerals 811 and 812).

The example of FIG. 8 indicates a state in which the tester #1 analysis target acquisition unit 810_1 acquires the block execution time lengths of the respective blocks with respect to the latest six wafers W among the block execution time lengths of the blocks with respect to the wafers W included in the graphs 711 to 716.

Similarly, the example of FIG. 8 indicates a state in which the tester #12 analysis target acquisition unit 810_12 acquires the block execution time lengths of the respective blocks with respect to the latest six wafers W among the block execution time lengths of the blocks with respect to the wafers W included in the graphs 801 to 806.

The tester #1 outlier removal unit 820_1 to the tester #12 outlier removal unit 820_12 remove a block execution time length that is the outlier from the block execution time lengths acquired by the tester #1 analysis target acquisition unit 810_1 to the tester #12 analysis target acquisition unit 810_12. Here, the tester #1 outlier removal unit 820_1 to the tester #12 outlier removal unit 820_12 may be configured to be operated all the time or may be configured to be operated only when instructed by the user of the prediction device 310.

The tester #1 prediction value calculation unit 830_1 to the tester #12 prediction value calculation unit 830_12 predict the block execution time length for each tester 150 and for each block by statistically processing the block execution time lengths obtained by removing the outlier. Here, the statistical processing includes any of processing of calculating a variance value, processing of calculating an average value, processing of calculating a median value, or processing of calculating a maximum value.

Additionally, the tester #1 prediction value calculation unit 830_1 to the tester #12 prediction value calculation unit 830_12 predict the test time length of the corresponding tester 150 by adding the prediction values of the block execution time lengths of the blocks of the corresponding tester 150 over all the blocks.

The example of FIG. 8 indicates a state in which the tester #1 prediction value calculation unit 830_1 calculates the prediction value of the block execution time length of each of the blocks (“TestBlock_1” to “TestBlock6”) of the tester 150 having the tester name=“tester #1”. Specifically, the example indicates a state in which the tester #1 prediction value calculation unit 830_1 calculates the block 1 execution time prediction value to the block 6 execution time prediction value. Additionally, the example indicates a state in which the tester #1 prediction value calculation unit 830_1 calculates the test time prediction value of the tester 150 having the tester name=“tester #1” by adding the block 1 execution time prediction value to the block 6 execution time prediction value.

Additionally, the example of FIG. 8 indicates a state in which the tester #12 prediction value calculation unit 830_12 calculates the prediction value of the block execution time length of each of the blocks (“TestBlock_1” to “TestBlock6”) of the tester 150 having the tester name=“tester #12”. Specifically, the example indicates a state in which the tester #12 prediction value calculation unit 830_12 calculates the block 1 execution time prediction value to the block 6 execution time prediction value. Additionally, the example indicates a state in which the tester #12 prediction value calculation unit 830_12 calculates the test time prediction value of the tester 150 having the tester name=“tester #12” by adding the block 1 execution time prediction value to the block 6 execution time prediction value.

### (3) Details of Table Generation Unit

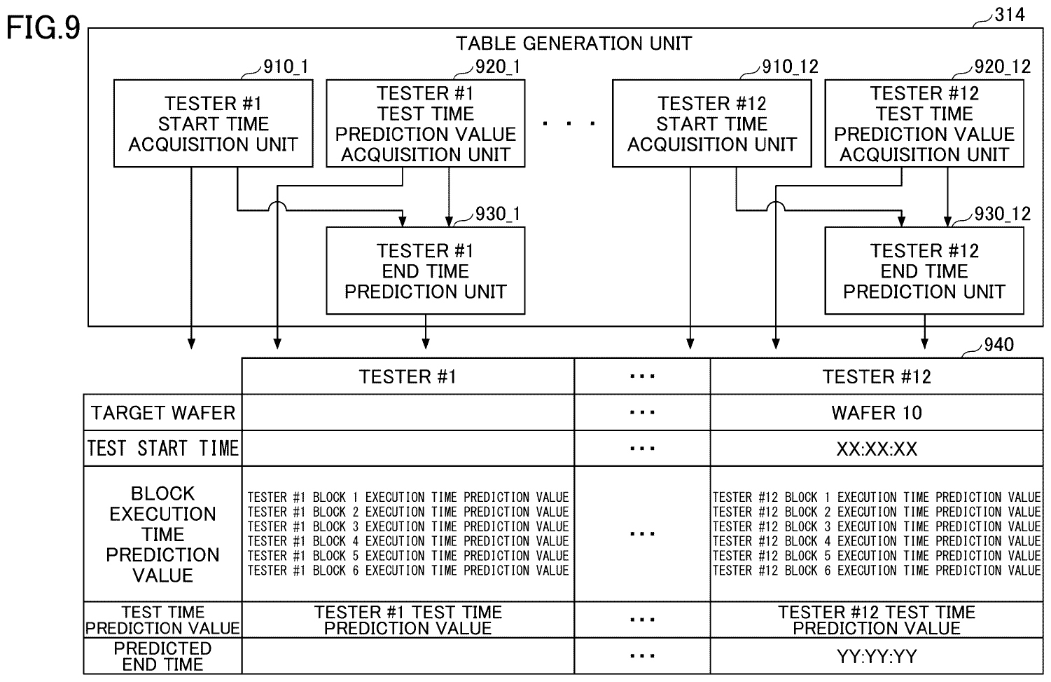

Next, a functional configuration of the table generation unit 314 and a specific example of a table generated by the table generation unit 314 will be described. FIG. 9 is a diagram illustrating an example of the functional configuration of the table generation unit and an example of the generated table.

As illustrated in FIG. 9, the table generation unit 314 includes:
a tester #1 start time acquisition unit 910_1 to a tester #12 start time acquisition unit 910_12;
a tester #1 test time prediction value acquisition unit 920_1 to a tester #12 test time prediction value acquisition unit 920_12; and
a tester #1 end time prediction unit 930_1 to a tester #12 end time prediction unit 930_12.

The tester #1 start time acquisition unit 910_1 to the tester #12 start time acquisition unit 910_12 acquire the time at which the execution of the block having the block name=“TestBlock_1” is started in the corresponding tester 150, and record the time in a table 940 as the test start time.

Additionally, the tester #1 start time acquisition unit 910_1 to the tester #12 start time acquisition unit 910_12 acquire the block execution start time of each block of the corresponding tester 150.

Further, the tester #1 start time acquisition unit 910_1 to the tester #12 start time acquisition unit 910_12 notify the tester #1 end time prediction unit 930_1 to the tester #12 end time prediction unit 930_12 of the acquired test start time and block execution start time.

The tester #1 test time prediction value acquisition unit 920_1 to the tester #12 test time prediction value acquisition unit 920_12 acquire the block execution time prediction values of each block and the test time prediction values of the corresponding tester 150 that are calculated in the tester #1 prediction value calculation unit 830_1 to the tester #12 prediction value calculation unit 830_12.

Additionally, the tester #1 test time prediction value acquisition unit 920_1 to the tester #12 test time prediction value acquisition unit 920_12 record the acquired block execution time prediction values of each block and test time prediction values in the table 940. Further, the tester #1 test time prediction value acquisition unit 920_1 to the tester #12 test time prediction value acquisition unit 920_12 notify the tester #1 end time prediction unit 930_1 to the tester #12 end time prediction unit 930_12 of the block execution time prediction values and the test time prediction values.

When acquiring the test start time of the corresponding tester 150, the tester #1 end time prediction unit 930_1 to the tester #12 end time prediction unit 930_12 add the test time prediction value of the corresponding tester 150 to the test start time. With this, the tester #1 end time prediction unit 930_1 to the tester #12 end time prediction unit 930_12 predict the test end time of the wafer W for which the test has just started. Further, the tester #1 end time prediction unit 930_1 to the tester #12 end time prediction unit 930_12 record the predicted test end time in the table 940 as predicted end time.

Additionally, when acquiring the block execution start time of the corresponding tester 150, the tester #1 end time prediction unit 930_1 to the tester #12 end time prediction unit 930_12 add, to the block execution start time of the block, the block execution time prediction values as of the block. With this, the tester #1 end time prediction unit 930_1 to the tester #12 end time prediction unit 930_12 predict the test end time at which the test of the wafer W currently being tested is completed. Further, the tester #1 end time prediction unit 930_1 to the tester #12 end time prediction unit 930_12 update the table 940 by using the predicted test end time as latest predicted end time.

As illustrated in FIG. 9, the table 940 includes “tester #1” to “tester #12” as information items. Additionally, the table 940 includes “target wafer”, “test start time”, “block execution time prediction value”, “test time prediction value”, and “predicted end time” as the information items.

In the table 940, “target wafer”, the “test start time”, and “predicted end time” of “tester #1” are blank because the test of the wafer W by the tester 150 having the tester name=“tester #1” is completed and the wafer W is being collected currently. Alternatively, this is because the wafer W that is the next test target is currently being transferred to the tester 150 having the tester name=“tester #1”. That is, “target wafer”, “test start time”, and “predicted end time” are deleted from the table 940 every time the test of the wafer W is completed.

With respect to the above, the test of the wafer W is completed and the block execution time length of each block and the test time length of the tester 150 having the tester name=“tester #1” are added to the measured data, and thus the block execution time prediction value and the test time prediction value are updated. As a result, the block execution time prediction value of each block and the test time prediction value after the update are recorded in “block execution time prediction value” and “test time prediction value”.

With respect to the above, the table 940 indicates that “tester #12” is currently testing the wafer W having the wafer name=“wafer 10” and that the test has been started at “XX:XX:XX”, i.e., “Hours:Minutes:Seconds”. Additionally, “block execution time prediction value” and “test time prediction value” record the block execution time prediction value of each block and the test time prediction value that are updated when the test of the previous wafer W (the wafer W having the wafer name=“wafer 9”) is completed. Further, “predicted end time” records the predicted end time (“YY:YY:YY”) predicted with respect to the wafer W having the wafer name=“wafer 10” currently being testes.

Here, the predicted end time (“YY:YY:YY”) is updated each time the block execution start time is acquired.

### <Flow of Prediction Process>

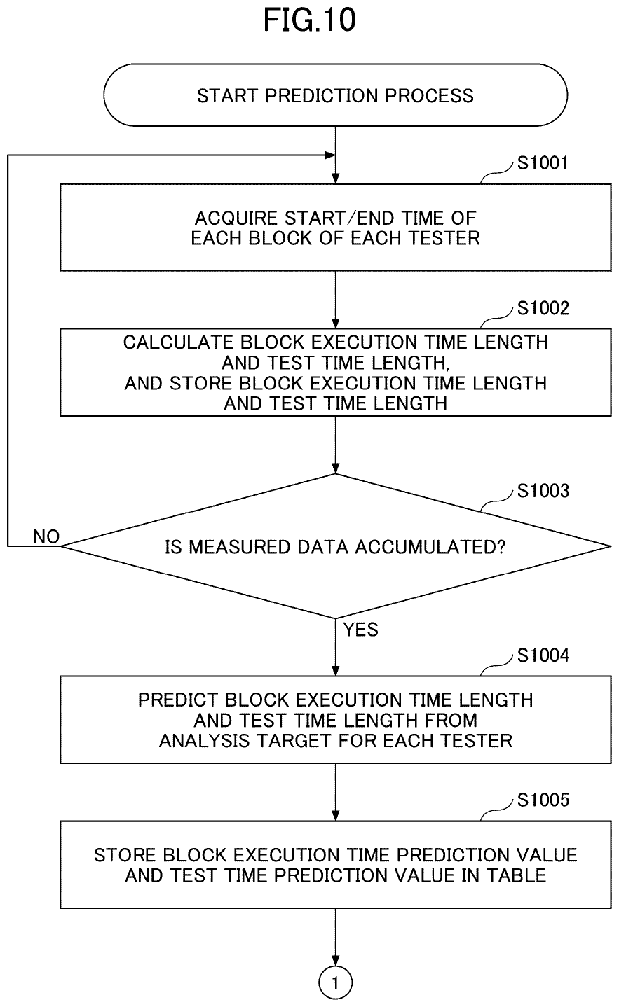

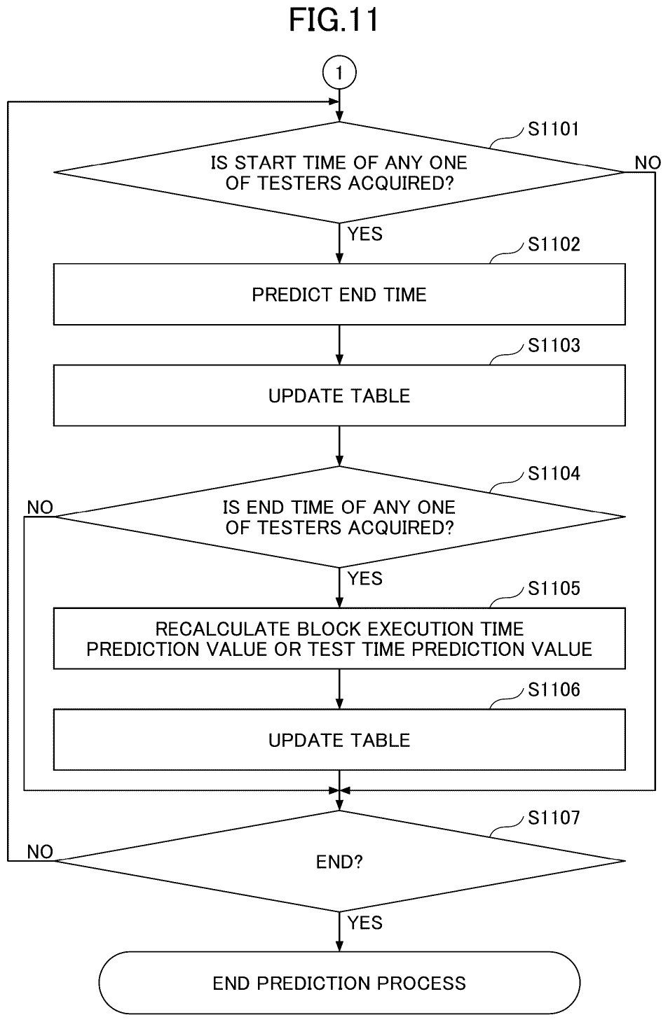

Next, a flow of a prediction process performed by the prediction device 310 will be described by using FIG. 10 and FIG. 11. FIG. 10 and FIG. 11 are first and second flowcharts illustrating the flow of the prediction process.

In step S1001 of FIG. 10, the measured data collection unit 311 acquires the test start time and the test end time of each tester 150 and the block execution start time and the block execution end time of each block of each tester 150 from the test device 110.

In step S1002, the measured data collection unit 311 calculates the test time length of each tester 150 based on the acquired test start time and test end time, and stores, as the measured data, the test time length in the measured data storage unit 312 together with the test start time and the test end time. Additionally, the measured data collection unit 311 calculates the block execution time length of each block of each tester 150 based on the acquired block execution start time and block execution end time of each block, and stores the block execution time length in the measured data storage unit 312 as the measured data.

In step S1003, the measured data collection unit 311 determines whether the measured data for a sufficient number of wafers W has been accumulated to predict the test time length of each tester and the block execution time length of each block of each tester.

If it is determined in step S1003 that the measured data is not accumulated (NO in step S1003), the process returns to step S1001.

If it is determined in step S1003 that the measured date for a sufficient number of wafers W is accumulated (YES in step S1003), the process proceeds to step S1004.

In step S1004, the test time prediction unit 313 reads the block execution time length of the analysis target among the block execution time lengths of the blocks of the testers 150 stored in the measured data storage unit 312, and predicts the block execution time length of each block of each tester 150. Additionally, the test time prediction unit 313 predicts the test time length of each tester 150 by adding the block execution time prediction values of the respective blocks of the tester 150 over all blocks for each tester 150.

In step S1005, the table generation unit 314 stores the test time prediction value of each tester 150 and the block execution time prediction value of each block of each tester 150, which are predicted by the test time prediction unit 313, in the table 940 of the table storage unit 315.

Subsequently, in step S1101 of FIG. 11, the measured data collection unit 311 determines whether the test start time of any of the testers 150 or the block execution start time of any of the blocks has been acquired. If it is determined in step S1101 that neither the test start time nor the block execution start time has been acquired (NO in step S1101), the process proceeds to step S1107.

If it is determined in step S1101 that the test start time or the block execution start time has been acquired (YES in step S1101), the process proceeds to step S1102.

In step S1102, the test time prediction unit 313 predicts the test end time by adding the test time prediction value to the test start time. Alternatively, the test time prediction unit 313 predicts the test end time by adding the block execution time prediction values as of the block to the block execution start time.

In step S1103, the table generation unit 314 updates the table 940 with the test start time and the test end time predicted by the test time prediction unit 313.

In step S1104, the measured data collection unit 311 determines whether the test end time (or the block execution end time) is acquired from any tester. If it is determined in step S1104 that the test end time (or the block execution end time) has not been acquired (NO in step S1104), the process proceeds to step S1107.

If it is determined in step S1104 that the test end time (or the block execution end time) has been acquired (YES in step S1104), the process proceeds to step S1105.

In step S1105, the measured data collection unit 311 calculates the test time length of the corresponding tester 150 (or the block execution time length of each block of the corresponding tester 150). Additionally, the test time prediction unit 313 recalculates the test time prediction value (or the block execution time prediction value of each block) by including the test time length (or the block execution time length of each block) calculated by the measured data collection unit 311.

In step S1106, the table generation unit 314 updates the table 940 with the test time prediction value (or the block execution time prediction value of each block) recalculated by the test time prediction unit 313.

In step S1107, the measured data collection unit 311 determines whether to end the prediction process, and if it is determined that the prediction process is not to be ended (NO in step S1107), the process returns to step S1101.

If it is determined in step S1107 that the prediction process is to be ended (YES in step S1107), the prediction process is ended.

### <Conclusion>

As is clear from the above description, the prediction device 310 according to the first embodiment
calculates the test time length when the wafer W is tested by the tester 150 included in the test device 110,
predicts the current test time length based on the calculated past test time lengths,
predicts the test end time of the wafer W of the test target based on the test time prediction value when the test start time of the wafer W of the test target of the test target by the tester 150 is acquired, and
stores at least the test time prediction value and the predicted end time in the table 940 in a readable manner.

With this, the prediction device 310 according to the first embodiment can improve the operation rate of the tester 150, in comparison with the case where the transfer section starts the operation after the tester 150 included in the test device 110 notifies that the test has ended. That is, according to the prediction device 310 of the first embodiment, appropriate information (table) for realizing an efficient transfer schedule by the transfer section of the test device 110 can be provided to the scheduling device 320.

Here, in the case of the prediction device 310 according to the first embodiment, the user of the prediction device 310 does not need to perform any setting on the prediction device 310, and can provide information contributing to an improvement in the operation rate of the tester only by accumulating the measured data.

### Second Embodiment

The above description of the first embodiment assumes that the table 940 generated by the table generation unit 314 is stored in the table storage unit 315 in an accessible manner to realize an efficient transfer schedule by the transfer section of the test device 110. However, the use of the table 940 generated by the table generation unit 314 is not limited to this.

For example, if the information recorded in the table 940 can be monitored, the operator of the test device 110 can specify the maintenance timing and check the abnormality of the test device 110.

That is, the table 940 stored in the table storage unit 315 can be used for the purpose of specifying the maintenance timing, checking abnormality, or the like by being visualized.

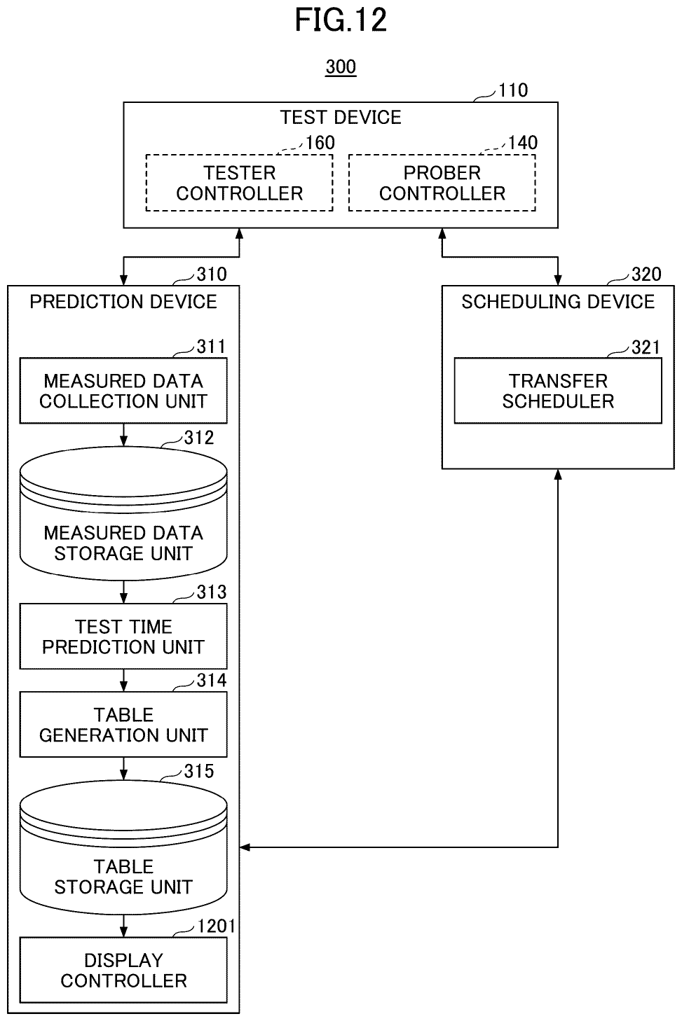

FIG. 12 is a second diagram illustrating an example of the system configuration of the test system. A difference from the system configuration described by using FIG. 3 is that, in FIG. 12, the prediction device 310 also functions as a display controller 1201.

The display controller 1201 accesses the table storage unit 315 in which the table 940 is stored in an accessible manner, and displays the table 940 to the operator of the test device 110 by visualizing the information recorded in the table 940 in real time.

This enables the operator of the test device 110 to monitor the information recorded in the table 940. As a result, the operator of the test device 110 can specify the maintenance timing of the test device 110 and perform the abnormality check of the test device 110.

Specifically, when the block execution time prediction values are different among the testers, there is a possibility that a contact failure due to dust at the tip of the probe of the tester 150 has occurred. Therefore, the operator of the test device 110 can specify the timing of the maintenance (probe tip polishing) of the corresponding tester 150. Additionally, the operator of the test device 110 can recognize the occurrence of disturbance (the temperature or the vibration), for example, by monitoring the block execution time prediction value.

### Third Embodiment

The above description of the first embodiment assumes that the prediction device 310 is disposed near the test device 110. However, the prediction device 310 may be disposed remotely relative to the test device 110. For example, the prediction device 310 may be implemented on a cloud.

Additionally, the above description of the first embodiment assumes that the prediction program is executed by the prediction device 310 alone. However, when the prediction device 310 is configured by multiple computers and the prediction program is installed in the multiple computers, for example, the prediction program may be executed in a form of a distributed computing.

Additionally, in the first embodiment described above, as an example of the method of installing the prediction program in the auxiliary storage device 403, the method of downloading and installing via a network, which is not illustrated, has been described. At this time, although the download source is not particularly mentioned, when the prediction program is installed by such a method, the download source may be, for example, a server device in which the prediction program is stored in an accessible manner. Additionally, the server device may be, for example, a device that receives access from the prediction device 310 via a network, which is not illustrated, and downloads the prediction program on the condition of charging. That is, the server device may be a device that performs a service of providing the prediction program on a cloud.

Additionally, in the first embodiment described above, when the prediction value of the test time length is calculated, the test time lengths of a predetermined number of latest wafers W are used. However, the analysis target used when the prediction value of the test time length is calculated is not limited thereto. For example, the prediction value of the test time length may be calculated using all of the test time length of the first wafer W to the test time length of the previous wafer W.

Additionally, in the first embodiment described above, as the method of calculating the prediction value of the test time length, a case of calculating any one of the variance, the average, the median, or the maximum value has been described, for example. However, the method of calculating the prediction value of the test time length is not limited to these, and the prediction value may be calculated by any other statistical processing.

Here, the present invention is not limited to the above-described configurations, such as the configurations described in the above-described embodiments, and combinations with other elements. In these respects, modifications can be made within the scope of the invention without departing from the spirit of the invention, and the configurations may be appropriately determined according to an application form.

This application claims priority to Japanese Patent Application No. 2021-212972 filed on Dec. 27, 2021, the entire contents of which are incorporated herein by reference.

### DESCRIPTION OF REFERENCE SYMBOLS

110: test device
112: test region
113: carry-in/out region
114: transfer region
140: prober controller
150: tester
160: tester controller
200: test program
300: test system
310: prediction device
311: measured data collection unit
312: measured data storage unit
313: test time prediction unit
314: table generation unit
315: table storage unit
320: scheduling device
321: transfer scheduler
610_1 to 610_12: tester #1 to tester #12 start/end time acquisition unit
620_1 to 620_12: tester #1 to tester #12 test time calculation unit
630: storage controller
810_1 to 810_12: tester #1 to tester #12 analysis target acquisition unit
820_1 to 820_12: tester #1 to tester #12 outlier removal unit
830_1 to 830_12: tester #1 to tester #12 prediction value calculation unit
910_1 to 910_12: tester #1 to tester #12 start time acquisition unit
920_1 to 920_12: tester #1 to tester #12 test time prediction value acquisition unit
930_1 to 930_12: tester #1 to tester #12 end time prediction unit
940: table
1201: display controller

1. A prediction device comprising:
a processor; and
a memory storing program instructions that cause the processor to:
calculate a test time length when a test of a wafer has been performed by a tester;
predict a current test time length based on past test time lengths calculated by the processor;
predict, when a start time of a test of a test target wafer by the tester is acquired, an end time of the test of the test target wafer based on the predicted test time length; and
store at least the predicted test time length and the predicted end time in a readable manner.

2. The prediction device as claimed in claim 1, wherein the program instructions cause the processor to predict the current test time length by statistically processing test time lengths of a predetermined number of wafers among the past test time lengths calculated by the processor.

3. The prediction device as claimed in claim 2, wherein the program instructions cause the processor to predict the current test time length by statistically processing test time lengths obtained by removing an outlier among the test time lengths of the predetermined number of wafers.

4. The prediction device as claimed in claim 2, wherein the program instructions cause the processor to predict the current test time length each time the test time length is calculated.

5. The prediction device as claimed in claim 1, wherein the program instructions cause the processor to predict the end time of the test of the test target wafer by adding the current test time length to the start time of the test of the test target wafer.

6. The prediction device as claimed in claim 5, wherein the program instructions cause the processor to predict the end time each time the start time is acquired.

7. The prediction device as claimed in claim 1,
wherein the test includes a plurality of blocks having test items different from each other,
wherein the program instructions cause the processor to calculate an execution time length of each of the plurality of blocks, and
wherein the program instructions cause the processor to predict the current test time length by predicting a current execution time length of each block based on a past execution time length of each block calculated by the processor and by adding the predicted current execution time length of each block.

8. The prediction device as claimed in claim 7, wherein the program instructions cause the processor to predict, when an execution start time of any one of the plurality of blocks is acquired, the end time of the test of the test target wafer based on an execution time length predicted for each block as of a block for which the execution start time is acquired.

9. The prediction device as claimed in claim 7, wherein the program instructions cause the processor to store the acquired start time and the predicted execution time length of each block in a readable manner.

10. The prediction device as claimed in claim 9,
wherein the predicted test time length and the predicted execution time length of each block are updated each time the test of the test target wafer is completed or each time execution of any one of the plurality of blocks is ended with respect to the test target wafer,
wherein the acquired start time is stored every time the test of the test target wafer is started, and
wherein the predicted end time is updated each time the test of the test target wafer is started or each time execution of any block of the plurality of blocks is started with respect to the test target wafer.

11. The prediction device as claimed in claim 1, wherein the program instructions cause the processor to delete the acquired start time and the predicted end time each time the test of the test target wafer is completed.

12. A test system comprising:
the prediction device as claimed in claim 1; and
a test device including a plurality of said testers and configured to test the wafer.

13. A prediction method comprising:
calculating a test time length when a test of a wafer has been performed by a tester;
predicting a current test time length based on past test time lengths calculated in the calculating of the test time length;
predicting, when a start time of a test of a test target wafer by the tester is acquired, an end time of the test of the test target wafer based on the predicted test time length; and
storing at least the predicted test time length and the predicted end time in a readable manner.

14. A non-transitory computer-readable recording medium having stored therein a prediction program for causing a computer to execute:
calculating a test time length when a test of a wafer has been performed by a tester;
predicting a current test time length based on past test time lengths calculated in the calculating of the test time length;
predicting, when a start time of a test of a test target wafer by the tester is acquired, an end time of the test of the test target wafer based on the predicted test time length; and
storing at least the predicted test time length and the predicted end time in a readable manner.
